(19) United States
(12) Patent Application Publication
(10) Pub. No.: US 2026/0070089 A1
(43) Pub. Date: Mar. 12, 2026

(54) CHIP FOR ULTRASONIC TRANSDUCER, ULTRASONIC TRANSDUCER, ELECTRONIC DEVICE, AND METHOD FOR PREPARING CHIP

(71) Applicant: HUIKE (SINGAPORE) HOLDING PTE.LTD., The Aries (SG)

(72) Inventors: Yuwang XU, Shenzhen, Guangdong (CN); Ya WEI, Shenzhen, Guangdong (CN); Lizhong ZENG, Shenzhen, Guangdong (CN); Canhong DU, Shenzhen, Guangdong (CN)

(73) Assignee: HUIKE (SINGAPORE) HOLDING PTE.LTD., The Aries (SG)

(21) Appl. No.: 19/390,510

(22) Filed: Nov. 15, 2025

Related U.S. Application Data
(63) Continuation of application No. PCT/CN2024/075346, filed on Feb. 1, 2024.

(51) Int. Cl. B06B 1/06; G06V 40/13; H10N 30/045

(52) U.S. Cl. CPC B06B 1/0692; G06V 40/1306; H10N 30/045

(57) ABSTRACT

A chip for an ultrasonic transducer, an ultrasonic transducer, an electronic device, and a method for preparing a chip are provided. The chip is arranged below an acoustic layer, and the chip comprises: a substrate; a circuit module arranged in the substrate; and a conductive shielding layer arranged between the circuit module and the acoustic layer, wherein a projection of the conductive shielding layer on the substrate at least covers a projection of the circuit module on the substrate, and the conductive shielding layer is grounded.

### CROSS-REFERENCE

The present disclosure is a continuation of international application No. PCT/CN2024/075346 filed on Feb. 1, 2024, and titled “CHIP FOR ULTRASONIC TRANSDUCER, ULTRASONIC TRANSDUCER, ELECTRONIC DEVICE, AND METHOD FOR PREPARING CHIP”, the entire contents of which are incorporated herein by reference.

### TECHNICAL FIELD

Embodiments of the present disclosure relate to the technical field of a sensor, and particularly relate to a chip for an ultrasonic transducer, an ultrasonic transducer, an electronic device, and a method for preparing a chip.

### BACKGROUND

An ultrasonic transducer comprises an acoustic layer and a chip, and the acoustic layer comprises, e.g., a piezoelectric layer, an upper electrode of the piezoelectric layer, and a protective layer. In an emission mode, the chip drives the piezoelectric layer to vibrate and emit an ultrasonic wave to a detected target. In a receiving mode, the chip recognizes surface structure of the detected object using a sound wave signal reflected from an acoustic path.

In a practical application of the ultrasonic transducer, a circuit module of the chip is arranged in a substrate below the acoustic layer, and a high voltage is required for polarization of the acoustic layer of the ultrasonic transducer, so that the high voltage will cause small-spacing metal blocks and suspended metal blocks in the circuit module to be easily broken down, thus affecting the yield of the chip.

### SUMMARY

In view of this, embodiments of the present disclosure provide a chip for an ultrasonic transducer, an ultrasonic transducer, an electronic device, and a method for preparing a chip, to at least partially solve the above technical problems.

According to an embodiment of the present disclosure, a chip for an ultrasonic transducer is provided, wherein the chip is arranged below an acoustic layer, and the chip comprises: a substrate; a circuit module arranged in the substrate; and a conductive shielding layer arranged between the circuit module and the acoustic layer, wherein a projection of the conductive shielding layer on the substrate at least covers a projection of the circuit module on the substrate, and the conductive shielding layer is grounded.

According to an embodiment of the present disclosure, an ultrasonic transducer is provided, comprising: the above chip and an acoustic layer.

According to an embodiment of the present disclosure, an electronic device is provided, comprising: a screen and the above ultrasonic transducer attached to the screen through a substrate of the ultrasonic transducer.

According to an embodiment of the present disclosure, a method for preparing a chip is provided, wherein the chip is configured to control an ultrasonic transducer, and the method comprises: guiding, during polarization of an acoustic layer of the ultrasonic transducer, induced charges above the acoustic layer to ground through a conductive shielding layer arranged between a circuit module and the acoustic layer, wherein a projection of the conductive shielding layer on a substrate at least covers a projection of the circuit module on the substrate.

Embodiments of the present disclosure provide a chip for an ultrasonic transducer, an ultrasonic transducer, an electronic device, and a method for preparing a chip. A conductive shielding layer is provided between a circuit module in a substrate and an acoustic layer, and a projection of the conductive shielding layer on the substrate at least covers a projection of the circuit module on the substrate. The conductive shielding layer guides induced charges above the acoustic layer of the ultrasonic transducer to ground. The embodiments of the present disclosure reduce the case where a high voltage generated during polarization of the acoustic layer will cause small-spacing metal blocks and suspended metal blocks in the circuit module to be easily broken down, thereby improving the yield of the chip.

### BRIEF DESCRIPTION OF DRAWINGS

To more clearly describe technical solutions of embodiments of the present disclosure or the prior art, drawings to be used in the description of the embodiments or the prior art will be briefly introduced below. Apparently, the drawings in the description below are merely some embodiments disclosed in the embodiments of the present disclosure. For those of ordinary skills in the art, other drawings may also be obtained based on these drawings.

FIG. 1 is a top view of an embodiment of an ultrasonic transducer according to the present disclosure;

FIG. 2 is a section view at A-A in FIG. 1;

FIG. 3 is a top view of another embodiment of an ultrasonic transducer according to the present disclosure;

FIG. 4 is a section view at A-A in FIG. 3;

FIG. 5 is a top view of another embodiment of an ultrasonic transducer according to the present disclosure;

FIG. 6 is a section view at A-A in FIG. 5;

FIG. 7 is a top view of another embodiment of an ultrasonic transducer according to the present disclosure;

FIG. 8 is a section view at A-A in FIG. 7;

FIG. 9 is a top view of another embodiment of an ultrasonic transducer according to the present disclosure;

FIG. 10 is a section view at A-A in FIG. 9;

FIG. 11 is a top view of another embodiment of an ultrasonic transducer according to the present disclosure;

FIG. 12 is a section view at A-A in FIG. 11;

FIG. 13 is a top view of another embodiment of an ultrasonic transducer according to the present disclosure;

FIG. 14 is a section view at A-A in FIG. 13;

FIG. 15 is a section view at A-A in FIG. 13;

FIG. 16 is a section view at A-A in FIG. 13;

FIG. 17 is a section view at A-A in FIG. 13;

FIG. 18 is a schematic diagram of an embodiment of an electronic device; and

FIG. 19 is a flowchart of a method for preparing a chip.

Description of reference numerals in the figures:
Chip 1000;
Pixel circuit area 100; Pixel electrode 110;
Chip ground module 200; Circuit module 300;
Metal bonding pad area 400;
Substrate 500; Metal layer 510; Top metal layer 5101; Multilayer metal layers 5102;
Passivation layer 520; First window 5201; Second window 5202;
Conductive shielding layer 600; Conductive layer 610;
Dielectric layer 620;
Redistribution layer 700;
Excitation electrode 800;
Acoustic layer 2000;
Piezoelectric layer 2100; Upper electrode 2200 of piezoelectric layer; and Protective layer 2300.

### DETAILED DESCRIPTION

To enable those skilled in the art to better understand technical solutions of embodiments of the present disclosure, the technical solutions of the embodiments of the present disclosure will be clearly and completely described below with reference to the drawings in the embodiments of the present disclosure. Apparently, the described embodiments are merely some, instead of all, of the embodiments of the present disclosure. All other embodiments obtained by those of ordinary skills in the art based on some embodiments among the embodiments of the present disclosure should be encompassed within the scope of protection of the embodiments of the present disclosure.

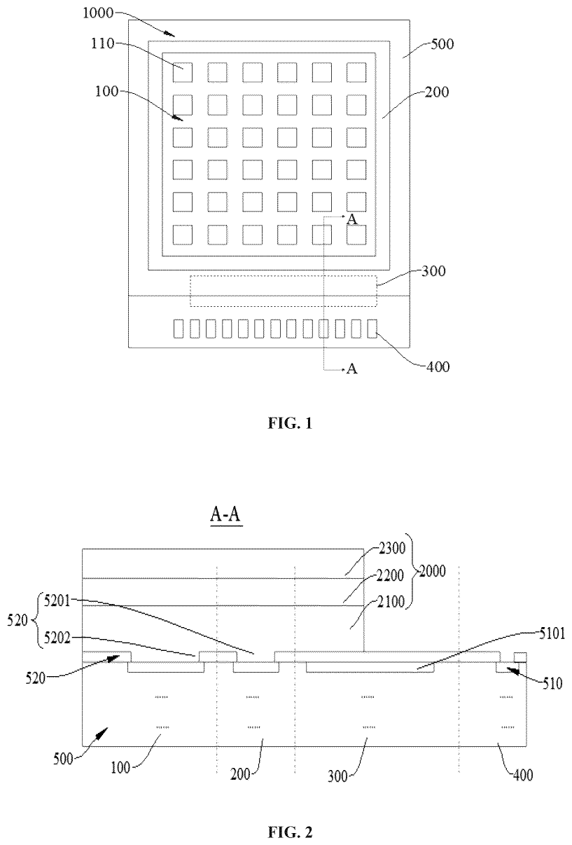

The structure of a chip 1000 in embodiments of the present disclosure is described in detail below in conjunction with FIGS. 1-17 of the specification. In order to facilitate observation of the structure of the chip 1000, an acoustic layer 2000 is omitted in FIGS. 1, 3, 5, 7, 9, 11, and 13.

Referring to FIGS. 1 and 2, FIG. 2 is description of a lateral structure along a section A-A in FIG. 1. The ultrasonic transducer comprises an acoustic layer 2000 and the chip 1000. The acoustic layer 2000 comprises a piezoelectric layer 2100, an upper electrode 2200 of the piezoelectric layer, and a protective layer 2300. The chip 1000 is arranged below the piezoelectric layer 2100 of the acoustic layer 2000. The chip 1000 comprises: a substrate 500, a pixel circuit area 100, a chip ground module 200, a circuit module 300, a metal bonding pad area 400, and an excitation electrode (not shown in the figure). A metal layer 510 above the metal bonding pad area 400 in FIG. 2 is a metal bonding pad, and a passivation layer above the metal bonding pad area 510 is provided with a window to expose a part of the metal bonding pad.

Specifically, the substrate 500 is a silicon-based substrate, the substrate 500 comprises a top metal layer 5101 thereabove, and the top metal layer 5101 comprises a passivation layer 520 thereabove. The substrate 500 comprises, e.g., some transistor units (such as an N-type or P-type metal oxide semiconductor field effect transistor, and a complementary metal oxide semiconductor field effect transistor composed of the two), intralayer metal wirings for interconnection, interlayer through holes, and multilayer metal layers 5102. “. . . ” in the figure is used only to represent the above transistor units, metal wirings, interlayer through holes, and multilayer metal layers 5102.

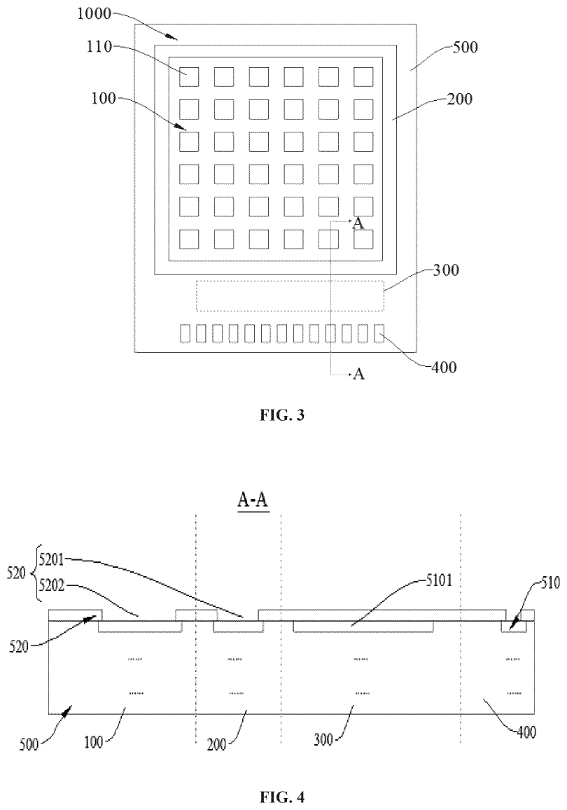

Referring to FIGS. 3 and 4, FIG. 4 is a schematic lateral structure along a section A-A in FIG. 3. The passivation layer 520 of the pixel circuit area 100 is provided with a second window 5202 to form a pixel electrode 110. The pixel circuit area 100 is an area of an ultrasonic transducer imaging array composed of some pixel electrodes 110, and is referred to as an Active Area (abbreviated as area AA). The chip ground module 200 is located on a periphery of the pixel circuit area 100, and is configured to isolate the pixel circuit area 100 to prevent the pixel circuit area 100 from being interfered by peripheral signals. The chip ground module 200 is arranged in parallel to the circuit module 300 in the substrate 500. The circuit module 300 is provided with a large number of metal wirings and functional circuits, such as power management, clock, and ADC circuits.

When the ultrasonic transducer is applied to the field of fingerprint recognition, a finger is placed on a screen cover plate, the ultrasonic transducer is in an emission mode, the pixel electrode 110 generates a lower voltage V1, the excitation electrode drives the upper electrode 2200 of the piezoelectric layer to generate an upper voltage V2, the lower voltage V1is subtracted from the upper voltage V2 to obtain a differential voltage, and the differential voltage drives the piezoelectric layer 2100 to vibrate and emit an ultrasonic wave. The ultrasonic wave reaches a surface of the finger through the screen cover plate, and intensity of a reflected echo signal of a sound wave from the fingerprint-cover plate interface varies due to a “valley”-“ridge” structure of a fingerprint. When the ultrasonic transducer is in a receiving mode, the pixel electrode 110 receives the reflected echo signal carrying fingerprint information, and transmits the received reflected echo signal to the circuit module 300. The circuit module 300 is configured to perform signal processing on the reflected echo signal collected by the pixel electrode.

Specifically, the circuit module comprises: an analog-to-digital conversion circuit configured to perform analog-to-digital conversion on the reflected echo signal collected by the pixel electrode; the circuit module further comprises a storage circuit configured to store the reflected echo signal after the analog-to-digital conversion; and the circuit module further comprises a fingerprint recognition circuit configured to process the reflected echo signal to confirm whether the fingerprint is a target fingerprint. The analog-to-digital conversion circuit, the storage circuit, and the fingerprint recognition circuit are not shown in the figure. In some embodiments, the fingerprint recognition circuit may also be implemented using another chip, which may be arranged to be connected to the ultrasonic transducer.

In an embodiment of the present disclosure, the ultrasonic transducer is placed inside a display apparatus to perform biometric feature recognition using the above process for user authentication.

In an embodiment of the present disclosure, the pixel electrode 110 is grounded through the metal wirings, the interlayer through holes, and the multilayer metal layers 5102 below the pixel electrode 110, thereby preventing the pixel electrode 110 from being interfered by a voltage signal of the acoustic layer 200.

In order to make the piezoelectric layer 2100 emit an ultrasonic wave, it is usually necessary to apply a high voltage signal of tens to hundreds of volts to the upper electrode 2200 of the piezoelectric layer. Since a high voltage is required for polarization of the piezoelectric layer 2100, the high voltage will cause small-spacing metal blocks and suspended metal blocks of the circuit module 300 to be easily broken down, thus affecting the yield of the chip.

In addition, there is overlap between projection areas of the circuit module 300 and the acoustic layer 2000 on the substrate 500, and the circuit module 300 will be easily interfered by a high voltage signal generated by the upper electrode 2200 of the piezoelectric layer, thereby increasing temporal domain noise of a signal in the circuit module, and reducing a signal-to-noise ratio of the signal.

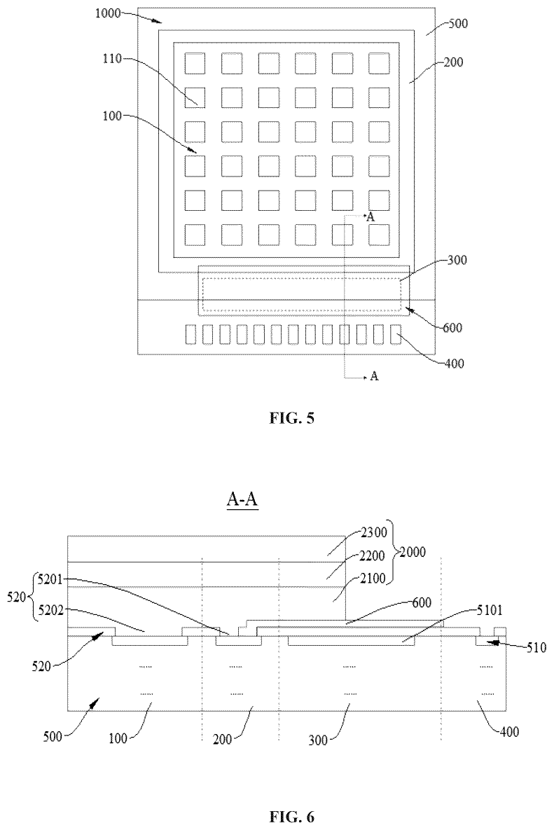

Referring to FIGS. 5 and 6, FIG. 6 is description of a lateral structure along a section A-A in FIG. 5. According to an embodiment of the present disclosure, a chip 1000 is arranged below an acoustic layer 2000. The acoustic layer 2000 comprises a piezoelectric layer 2100, an upper electrode 2200 of the piezoelectric layer, and a protective layer 2300. The chip 1000 comprises: a substrate 500, a circuit module 300, and a conductive shielding layer 600. The conductive shielding layer 600 is arranged between the circuit module 300 and the acoustic layer 2000, a projection of the conductive shielding layer 600 on a substrate 500 at least covers a projection of the circuit module 300 on the substrate 500, and the conductive shielding layer 600 is grounded.

According to an embodiment of the present disclosure, the chip 1000 is provided with the conductive shielding layer 600, the conductive shielding layer 600 is arranged between the circuit module 300 and the acoustic layer 2000, the projection of the conductive shielding layer 600 on the substrate 500 at least covers the projection of the circuit module 300 on the substrate 500, and the conductive shielding layer 600 is connected to the chip ground module 200. During polarization manufacturing of the acoustic layer 2000, the presence of the conductive shielding layer 600 further effectively reduces the occurrence of breakdown of small-spacing metal blocks and suspended metal blocks in the circuit module 300, thereby ensuring the yield of the chip manufacturing.

In some other specific implementations of the present disclosure, the circuit module 300 is arranged in the substrate 500, and at least a part of the circuit module 300 is located below the acoustic layer. When the acoustic layer 2000 generates an ultrasonic signal, induced charges above the acoustic layer 2000 are guided to ground through the conductive shielding layer 600, thereby reducing the interference of the high voltage signal generated by the upper electrode 2200 of the piezoelectric layer of the chip 1000 with the circuit module 300, and improving a signal-to-noise ratio of the signal.

In some specific implementations of an embodiment of the present disclosure, referring to FIGS. 5 and 6, the chip ground module 200 is arranged in parallel to the circuit module 300 in the substrate 500, a passivation layer 520 above the chip ground module 200 is provided with a first window 5201, a metal layer 510 above the chip ground module 200 is exposed through the first window 5201, at least a part of the conductive shielding layer 600 is connected to the metal layer 510 above the chip ground module 200 through the first window 5201, and the conductive shielding layer 600 is grounded through the metal layer 510 above the chip ground module 200.

In an embodiment of the present disclosure, the passivation layer above the chip ground module 200 is simply provided with the first window 5201, so that the conductive shielding layer 600 can be grounded through the metal layer 510 of the chip ground module 200, and the manufacturing is simpler.

In some embodiments of the present disclosure, thickness of the conductive shielding layer 600 is smaller than or equal to 10 μm. Specifically, the thickness of the conductive shielding layer 600 is preferably smaller than 1 μm, thereby preventing the conductive shielding layer 600 with a large thickness from affecting the uniformity of the piezoelectric layer 2100.

In some embodiments of the present disclosure, the conductive shielding layer 600 may comprise one of a metal material, a metal oxide semiconductor material, an organic conductive material, a nano-metal conductive material, or a nano-carbon conductive material.

Specifically, the metal material may be a common metal material such as aluminum, titanium, copper, or tungsten. The metal oxide semiconductor material may be, e.g., tin oxide (SnO), zinc oxide (ZnO), indium tin oxide (ITO), indium zinc oxide (IZO), and indium gallium zinc oxide (IGZO). The organic conductive material may be, e.g., polythiophene, poly(p-styrene) (PEDOT), and poly(3,4-ethylenedioxythiophene)-polystyrene sulfonic acid (PEDOT:PSS). The nano-metal conductive material may be, e.g., silver nanowires (AgNWs) and metal meshes. The nano-carbon conductive material may be, e.g., graphene and carbon nanotubes.

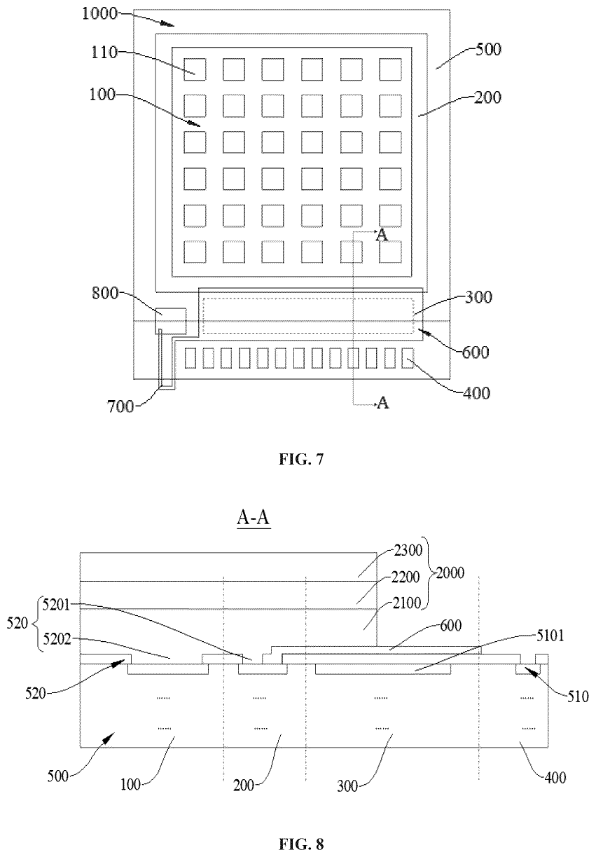

In some other specific implementations of an embodiment of the present disclosure, referring to FIGS. 7 and 8, FIG. 8 is description of a lateral structure along a section A-A in FIG. 7. The chip 1000 further comprises a Redistribution Layer (RDL) 700. One terminal of the redistribution layer 700 is connected to the conductive shielding layer 600, and the other terminal of the redistribution layer 700 is electrically connected to the excitation electrode 800 during the polarization of the acoustic layer.

Specifically, the redistribution layer 700 may be a metal redistribution layer, which is located on a lateral side of the conductive shielding layer 600. In order to facilitate the connection of the other terminal of the redistribution layer 700 to the excitation electrode 800, the redistribution layer 700 is arranged on a lateral side of the conductive shielding layer 600 close to the excitation electrode 800.

During the polarization of the acoustic layer 2000, the excitation electrode 800 is electrically connected to the conductive shielding layer 600 through the redistribution layer 700, the excitation electrode 800 may be a suspended metal structure, and polarization-induced charges accumulated by the excitation electrode 800 during the polarization of the acoustic layer 2000 are discharged to the ground, thereby preventing the excitation electrode 800 from being broken down due to the accumulation of the polarization-induced charges.

Since the excitation electrode 800 is configured to provide an excitation voltage to the upper electrode 2200 of the piezoelectric layer during operation of the ultrasonic transducer, the excitation electrode 800, when grounded, fails to provide the excitation voltage to the upper electrode 2200 of the piezoelectric layer. Therefore, after the chip is prepared, the excitation electrode 800 will be disconnected from the redistribution layer 700, so that the excitation electrode 800 is disconnected from the conductive shielding layer 600, and the excitation electrode 800 is no longer grounded.

After the preparation of a plurality of chips in a wafer is completed, the plurality of chips in the wafer can be selected for testing. After the preparation of the plurality of chips in the wafer is completed or the testing of the plurality of chips in the wafer is completed, the wafer where the plurality of chips are located is cut to form a single chip, that is, the chip. In this embodiment, a length of the redistribution layer 700 exceeds a boundary of a to-be-cut single chip in the wafer, and at least a part of the redistribution layer is arranged in a cutting path on a wafer corresponding to the single chip, so that when the wafer is cut, the excitation electrode 800 is disconnected from the redistribution layer 700, and the excitation electrode 800 can no longer be grounded without the need to additionally provide other processes.

Specifically, materials and manufacturing processes of the redistribution layer 700 and the conductive shielding layer 600 are consistent, thereby simplifying the manufacturing process.

In order to further simplify the manufacturing processes, the redistribution layer 700 is formed synchronously with the conductive shielding layer 600.

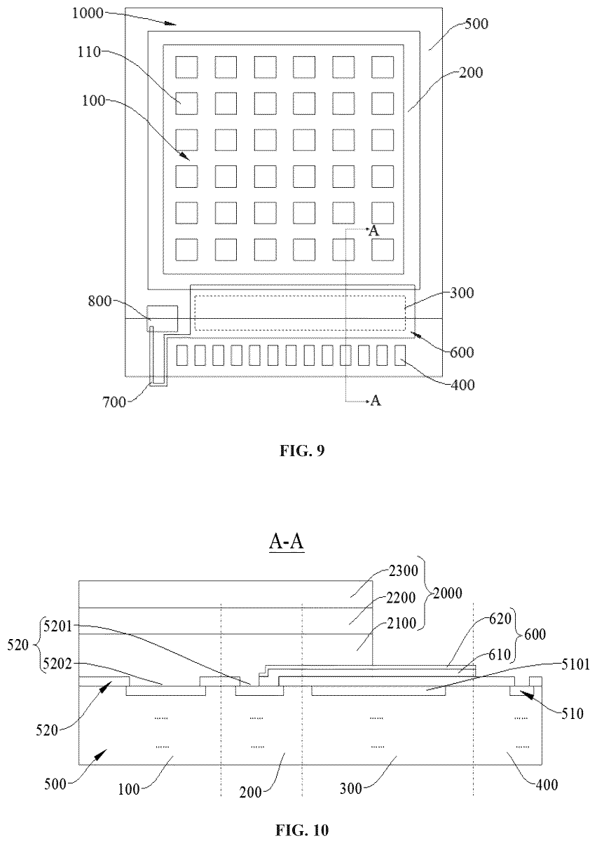

In some other specific implementations of an embodiment of the present disclosure, referring to FIGS. 9 and 10, FIG. 10 is description of a lateral structure along a section A-A in FIG. 9. The conductive shielding layer 600 comprises a conductive layer 610 and a dielectric layer 620 adapted in shape. The conductive layer 610 is arranged between the circuit module 300 and the dielectric layer 620, and the dielectric layer 620 is arranged between the conductive layer 610 and the acoustic layer 2000 (piezoelectric layer 2100). Therefore, it can be understood that at least a part of the conductive layer 610 is connected to the chip ground module 200, and the circuit module 300 is separated from the acoustic layer 2000, so that when the acoustic layer 2000 generates an ultrasonic signal, the induced charges above the acoustic layer 2000 can be guided to the ground through the conductive shielding layer, thereby reducing the interference with the circuit module 300. The dielectric layer 620 covers above the conductive layer 610, and the shape of the dielectric layer 620 is adapted to the conductive layer 610. The dielectric layer 620 can avoid the problem such as poor bonding force between the piezoelectric layer 2100 of the acoustic layer 2000 and the conductive layer 610.

Specifically, the dielectric layer 620 may be at least one of a silicon oxide, a silicon nitride, a material with a high-K dielectric constant, and a polymer dielectric material. The high K of the material with the high-K dielectric constant is defined relative to a material with a relative dielectric constant. The material with the high-K dielectric constant may be, e.g., a titanium oxide, a zirconium oxide, or a hafnium oxide. The polymer dielectric material may be, e.g., polyimide.

Specifically, the redistribution layer 700 is formed synchronously with the conductive shielding layer 600. When the conductive shielding layer 600 comprises a conductive layer 610 and a dielectric layer 620, the redistribution layer 700 also comprises a conductive layer 610 and a dielectric layer 620.

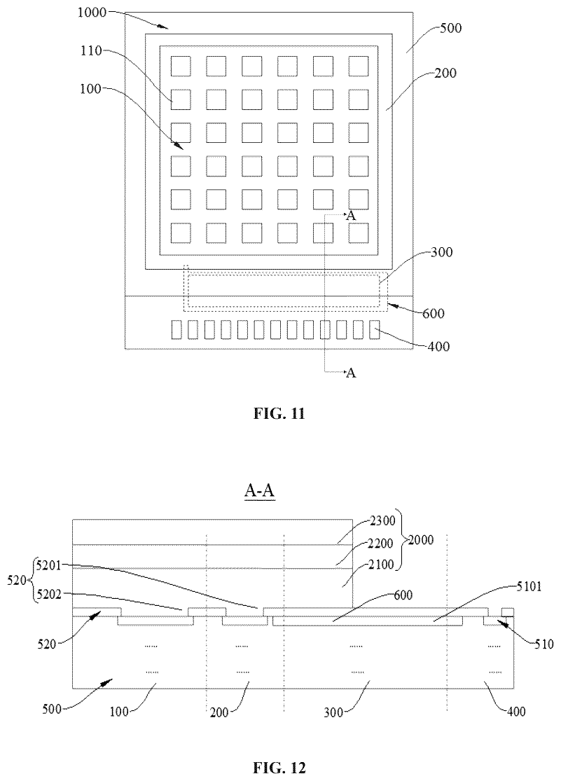

In some other specific implementations of an embodiment of the present disclosure, referring to FIGS. 11 and 12, FIG. 12 is description of a lateral structure along a section A-A in FIG. 11. The conductive shielding layer 600 is at least a part of a top metal layer 5101 above the circuit module 300, and the conductive shielding layer 600 is grounded through an intralayer wiring of the substrate 500 (not shown in the figure). In an embodiment of the present disclosure, the top metal layer 5101 above the circuit module 300 is multiplexed, the conductive shielding layer 600 is formed synchronously with the top metal layer 5101 above the circuit module 300, without the need to arrange a separate conductive shielding layer 600, so that the manufacturing is simpler, thereby improving the manufacturing efficiency, and reducing the costs. Moreover, the conductive shielding layer 600 is at least a part of the top metal layer 5101 above the circuit module 300, without the need to arrange a dielectric layer to avoid the problem such as poor bonding force between the piezoelectric layer 2100 of the acoustic layer 2000 and the conductive layer 610.

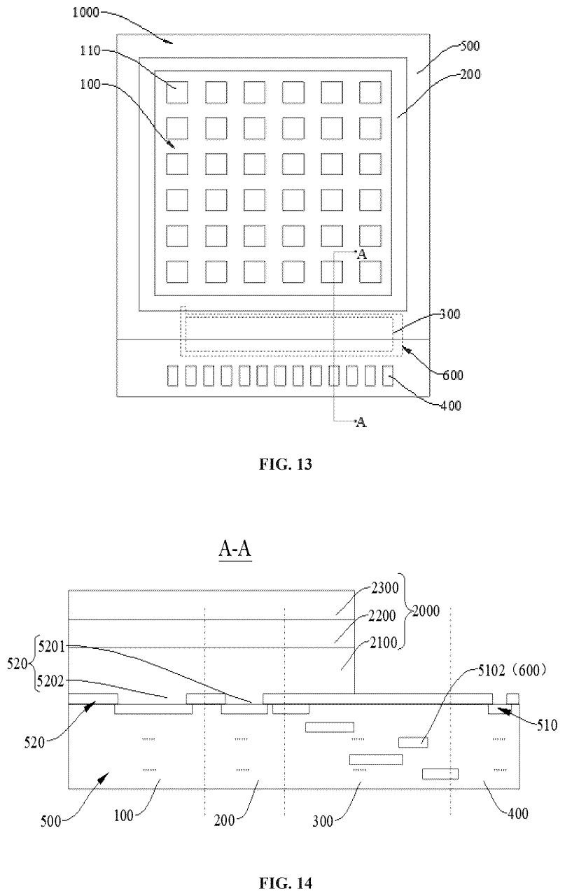

In some other specific implementations of an embodiment of the present disclosure, referring to FIGS. 13-17, FIGS. 14-17 are description of a lateral structure along a section A-A in FIG. 13. The conductive shielding layer 600 comprises at least a part of the multilayer metal layers 5102 in the substrate 500, the multilayer metal layers 5102 are grounded through a part of at least one metal layer 510 thereamong, and the multilayer metal layers 5102 are located in a plurality of planes parallel to each other.

Projections of the multilayer metal layers 5102 on the substrate 500 cover a projection of the circuit module 300, thereby improving the arrangement flexibility of the multilayer metal layers 5102 based on actual design of the chip 1000. That is, the multilayer metal layers 5102 are arranged at different positions of the chip 1000 respectively, which not only can ensure the protection effects of the circuit module 300, but also can achieve flexible arrangement.

Specifically, at least one of the multilayer metal layers 5102 in an embodiment of the present disclosure is grounded through the intralayer wiring (not shown in the figure), and each of the remaining ones is connected to the grounded metal layer 5102 through the intralayer wiring (not shown in the figure), or each of the metal layers 5102 is grounded through the intralayer wiring (not shown in the figure).

If a single metal layer 5102 fails to completely cover the circuit module 300, another metal layer 5102 may be arranged to superpose projection areas on the substrate 500 with the previous metal layer 5102, so that projections of the two metal layers 5102 on the substrate 500 can cover the projection of the circuit module 300 on the substrate 500. Similarly, the arrangements of three metal layers 5102 and four metal layers 5102 have same effects.

Further, as shown in FIGS. 14-17, there is pairwise overlap between projections of multiple metal layers 5102 on the substrate 500. Therefore, the projections of the multiple metal layers 5102 on the substrate 500 can completely cover the projection of the circuit module 300 on the substrate 500, thereby preventing gaps among the projections of the multiple metal layers 5102 on the substrate 500 from reducing protection effects on the circuit module 300.

In some embodiments of the present disclosure, the number of metal layers 5102 may be any number, and may be adjusted based on actual structural layout of the chip 1000.

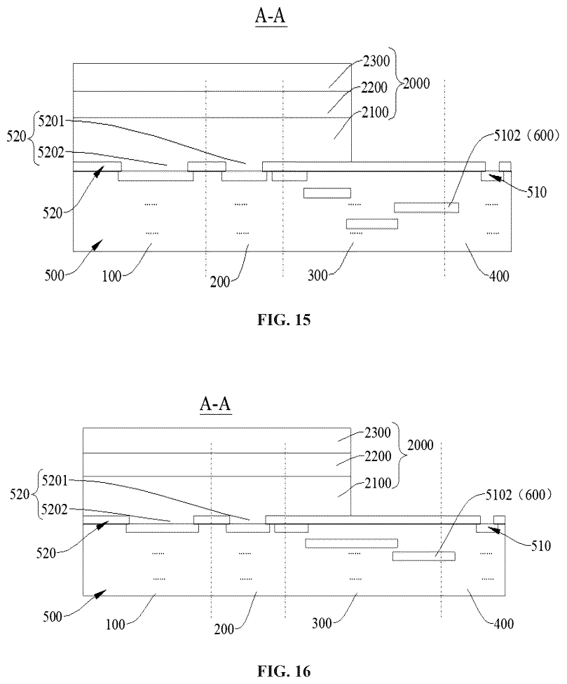

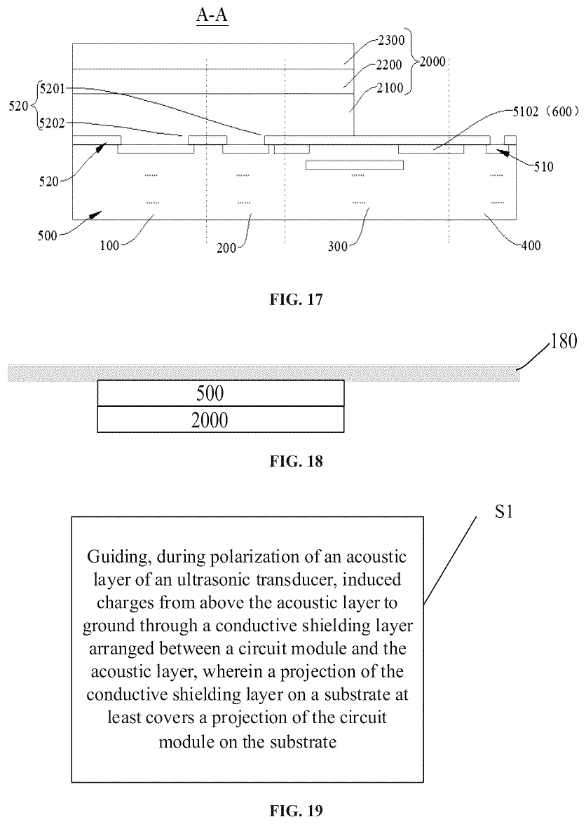

As shown in FIG. 14, the conductive shielding layer 600 comprises five metal layers 5102, and a part of the five metal layers 5102 is grounded (grounding positions not shown in the figure). Moreover, projected areas on the substrate formed by the grounded part of the metal layers 5102 completely cover the projection of the circuit module 300 on the substrate. Therefore, with this arrangement, the conductive shielding layer 600 composed of the five metal layers 5102 protects the circuit module 300. As shown in FIG. 15, the conductive shielding layer 600 may further comprise four metal layers 5102. As shown in FIG. 16, the conductive shielding layer 600 may further comprise three metal layers 5102. As shown in FIG. 17, the conductive shielding layer 600 also comprises three metal layers 5102. However, the layout of the three metal layers 5102 in FIG. 17 is different from the layout of the three metal layers 5102 in FIG. 16. Therefore, it can be understood that the layout of the multiple metal layers 5102 may be diverse, thereby diversifying the chip structure of the chip 1000.

In addition, the arrangement of the number of metal layers 5102 is not limited to five or three in the above embodiments, and different numbers may be arranged based on actual use requirements, depending on design of the chip 1000.

Specifically, when the conductive shielding layer 600 is a part of the multilayer metal layers 5102 in the substrate 500, a dielectric layer (not shown in the figure) in the substrate is arranged between the conductive shielding layer 600 and the passivation layer 520, and the dielectric layer in the substrate may be a silicon oxide layer.

Moreover, the conductive shielding layer 600 comprises at least a part of the multilayer metal layers 5102 in the substrate 500, without the need to arrange a dielectric layer to avoid the problem such as poor bonding force between the piezoelectric layer 2100 of the acoustic layer 2000 and the conductive layer 610.

In some embodiments of the present disclosure, a square resistance of the conductive shielding layer 600 is between 0.1 Ω/□ and M Ω/□. Specifically, value of the square resistance of the conductive shielding layer 600 can be selected based on actual use, so as to ensure the effects of shielding induced charges of a working voltage of the acoustic layer 2000.

In addition, the film forming mode of the conductive shielding layer 600 of the chip 1000 in an embodiment of the present disclosure may be, for example, film forming using a metal material or a metal oxide semiconductor material by physical vapor deposition (PVD), such as sputtering or evaporation, or film forming by chemical vapor deposition (CVD), such as plasma enhanced chemical vapor deposition (PECVD), atmospheric pressure chemical vapor deposition (APCVD), low pressure chemical vapor deposition (LPCVD), or metal organic chemical vapor deposition (MOCVD), or film forming by atomic layer deposition (ALD). If an organic conductive material, a nano-metal conductive material or a nano-carbon material is selected, film forming may be further implemented in a series of solution coating modes such as spin coating, spray coating, roller coating, or slit coating. The conductive shielding layer 600 may be graphed by lift-off, dry etching, or wet etching. The lift-off can be understood as a lift-off process, which is obtaining a patterned photoresist structure or a metal shadow mask on a substrate using a photoetching process, coating a target coating on the mask using a coating process, and then dissolving the photoresist in a dephotoresisting solution (also known as a lift-off solution) or mechanically removing a hard metal mask, to obtain a target graphical structure consistent with a pattern. Moreover, the redistribution layer 700 may be formed in a same way.

Referring to FIGS. 1-17, an embodiment of the present disclosure further provides an ultrasonic transducer, comprising: a chip 1000 and an acoustic layer 2000, and the chip 1000 is the chip 1000 according to any one of the above embodiments.

Referring to FIG. 18, an embodiment of the present disclosure further provides an electronic device, comprising: a screen 180 and the above ultrasonic transducer attached to the screen 180 through a substrate 500 of the ultrasonic transducer.

Referring to FIG. 19, an embodiment of the present disclosure further provides a method for preparing a chip configured to control an ultrasonic transducer, comprising:

Step S1: guiding, during polarization of an acoustic layer of the ultrasonic transducer, induced charges above the acoustic layer to ground through a conductive shielding layer arranged between a circuit module and the acoustic layer, wherein a projection of the conductive shielding layer on a substrate at least covers a projection of the circuit module on the substrate.

According to an embodiment of the present disclosure, the chip is provided with the conductive shielding layer, the conductive shielding layer is arranged between the circuit module and the acoustic layer, the projection of the conductive shielding layer on the substrate at least covers the projection of the circuit module on the substrate, and the conductive shielding layer is connected to the chip ground module. During polarization manufacturing of the acoustic layer, the presence of the conductive shielding layer effectively reduces the occurrence of breakdown of small-spacing metal blocks and suspended metal blocks in the circuit module, thereby ensuring the yield of the chip manufacturing.

Specifically, the step S1 further comprises: guiding charges accumulated by the excitation electrode to the ground through a redistribution layer and the conductive shielding layer, wherein one terminal of the redistribution layer is connected to the conductive shielding layer, and the other terminal of the redistribution layer is electrically connected to the excitation electrode.

The method further comprises:

Disconnecting the excitation electrode from the redistribution layer when the chip is prepared.

During the polarization of the acoustic layer, the excitation electrode is electrically connected to the conductive shielding layer through the redistribution layer, the excitation electrode may be a suspended metal structure, and polarization-induced charges accumulated by the excitation electrode during the polarization of the acoustic layer are discharged to the ground, thereby preventing the excitation electrode from being broken down due to the accumulation of the polarization-induced charges.

Since the excitation electrode is configured to provide an excitation voltage to the upper electrode of the piezoelectric layer during operation of the ultrasonic transducer, the excitation electrode, when grounded, fails to provide the excitation voltage to the upper electrode of the piezoelectric layer. Therefore, after the polarization of the acoustic layer is completed, excitation electrode will be disconnected from the redistribution layer, so that the excitation electrode is disconnected from the conductive shielding layer, and the excitation electrode is no longer grounded.

Since the excitation electrode is configured to provide an excitation voltage to the upper electrode of the piezoelectric layer during operation of the ultrasonic transducer, the excitation electrode, when grounded, fails to provide the excitation voltage to the upper electrode of the piezoelectric layer. Therefore, after the chip is prepared, the excitation electrode will be disconnected from the redistribution layer, so that the excitation electrode is disconnected from the conductive shielding layer, and the excitation electrode is no longer grounded.

After the preparation of a plurality of chips in a wafer is completed, the plurality of chips in the wafer can be selected for testing. After the preparation of the plurality of chips in the wafer is completed or the testing of the plurality of chips in the wafer is completed, the wafer where the plurality of chips are located is cut to form a single chip, that is, the chip. In this embodiment, a length of the redistribution layer exceeds a boundary of a to-be-cut single chip in the wafer, and at least a part of the redistribution layer is arranged in a cutting path on a wafer corresponding to the single chip, so that when the wafer is cut, the excitation electrode is disconnected from the redistribution layer, and the excitation electrode can no longer be grounded without the need to additionally provide other processes.

The above embodiments are only used to illustrate the embodiments of the present disclosure, and are not intended to limit the embodiments of the present disclosure. Those of ordinary skills in the relevant technical field may further make various alterations and modifications without departing from the spirit and scope of the embodiments of the present disclosure. Therefore, all equivalent technical solutions are also encompassed within the scope of the embodiments of the present disclosure, and the scope of patent protection of the embodiments of the present disclosure should be defined by the claims.

1. A chip for an ultrasonic transducer, arranged below an acoustic layer and comprising:
a substrate;
a circuit module arranged in the substrate; and
a conductive shielding layer arranged between the circuit module and the acoustic layer, wherein a projection of the conductive shielding layer on the substrate at least covers a projection of the circuit module on the substrate, and the conductive shielding layer is grounded.

2. The chip according to claim 1, wherein at least a part of the circuit module is located below the acoustic layer.

3. The chip according to claim 1, wherein the chip further comprises: a chip ground module arranged in parallel to the circuit module in the substrate; and
a passivation layer above the chip ground module is provided with a first window, a metal layer above the chip ground module is exposed through the first window, at least a part of the conductive shielding layer is connected to the metal layer above the chip ground module through the first window, and the conductive shielding layer is grounded through the metal layer above the chip ground module.

4. The chip according to claim 1, wherein the chip further comprises a redistribution layer and an excitation electrode, one terminal of the redistribution layer is connected to the conductive shielding layer, and the other terminal of the redistribution layer is electrically connected to the excitation electrode during polarization of the acoustic layer.

5. The chip according to claim 4, wherein a length of the redistribution layer exceeds a boundary of the chip, and at least a part of the redistribution layer is arranged in a cutting path of the chip.

6. The chip according to claim 5, wherein after the chip is prepared, the redistribution layer is disconnected from the excitation electrode.

7. The chip according to claim 1, wherein the conductive shielding layer comprises a conductive layer and a dielectric layer adapted in shape, the conductive layer is arranged between the circuit module and the dielectric layer, and the dielectric layer is arranged between the conductive layer and the acoustic layer.

8. The chip according to claim 7, wherein the redistribution layer is formed synchronously with the conductive shielding layer.

9. The chip according to claim 1, wherein the conductive shielding layer is at least a part of a top metal layer above the circuit module, and the conductive shielding layer is grounded through an intralayer wiring of the substrate.

10. The chip according to claim 1, wherein the conductive shielding layer is at least a part of multilayer metal layers above the circuit module, the multilayer metal layers are grounded through a part of at least one metal layer thereamong, the multilayer metal layers are located in a plurality of planes parallel to each other, and a dielectric layer in the substrate is arranged between the conductive shielding layer and a passivation layer thereabove.

11. The chip according to claim 10, wherein there is pairwise overlap between projections of the multilayer metal layers on the substrate.

12. The chip according to claim 4, wherein the chip further comprises:
a pixel circuit area, wherein a second window is arranged on a passivation layer above the pixel circuit area, a metal layer above the pixel circuit area is exposed through the second window to form a pixel electrode, and the chip ground module is arranged on a periphery of the pixel circuit area; and
the pixel electrode outputs a drive signal to drive a piezoelectric layer to vibrate and emit an ultrasonic wave in an emission mode, and the pixel electrode receives a reflected echo signal and transmits the reflected echo signal to the circuit module for signal processing in a receiving mode.

13. The chip according to claim 12, wherein the circuit module comprises:
an analog-to-digital conversion circuit configured to perform analog-to-digital conversion on the reflected echo signal collected by the pixel electrode;
the circuit module further comprises a storage circuit configured to store the reflected echo signal after the analog-to-digital conversion; and
the circuit module further comprises a fingerprint recognition circuit configured to process the reflected echo signal to confirm whether it is a target fingerprint.

14. The chip according to claim 13, wherein the acoustic layer comprises the piezoelectric layer, an upper electrode of the piezoelectric layer and a protective layer, the chip is arranged below the piezoelectric layer, the excitation electrode drives the upper electrode of the piezoelectric layer to generate an upper voltage, the pixel electrode generates a lower voltage, the lower voltage is subtracted from the upper voltage to obtain a differential voltage, and the differential voltage drives the piezoelectric layer to vibrate and emit an ultrasonic wave.

15. The chip according to claim 1, wherein a square resistance of the conductive shielding layer is between 0.1 Ω/□ and M Ω/□.

16. The chip according to claim 1, wherein the conductive shielding layer has a thickness smaller than 1μm.

17. An ultrasonic transducer, comprising:
a chip and an acoustic layer, wherein the chip is the chip according to claim 1.

18. An electronic device, comprising: a screen and the ultrasonic transducer according to claim 17, wherein the ultrasonic transducer is attached to the screen through a substrate of the ultrasonic transducer.

19. A method for preparing a chip configured to control an ultrasonic transducer, comprising:
guiding, during polarization of an acoustic layer of the ultrasonic transducer, induced charges above the acoustic layer to ground through a conductive shielding layer arranged between a circuit module and the acoustic layer, wherein a projection of the conductive shielding layer on a substrate at least covers a projection of the circuit module on the substrate.

20. The method according to claim 19, wherein guiding, during the polarization of the acoustic layer of the ultrasonic transducer, the induced charges above the acoustic layer to the ground further comprises:
guiding charges accumulated by an excitation electrode to the ground through a redistribution layer and the conductive shielding layer, wherein one terminal of the redistribution layer is connected to the conductive shielding layer, and the other terminal of the redistribution layer is electrically connected to the excitation electrode; and
the method further comprises: disconnecting the excitation electrode from the redistribution layer when the chip is prepared, wherein a length of the redistribution layer exceeds a boundary of the chip, and at least a part of the redistribution layer is arranged in a cutting path of the chip.
